(19) United States
(12) Patent Application Publication
(10) Pub. No.: US 2026/0223367 A1
(43) Pub. Date: Jul. 30, 2026

(54) SEMICONDUCTOR STORAGE DEVICE AND MANUFACTURING METHOD THEREOF

(71) Applicant: Kioxia Corporation, Tokyo (JP)

(72) Inventors: Wataru HASEGAWA, Yokkaichi (JP); Takuya KONNO, Yokkaichi (JP)

(73) Assignee: Kioxia Corporation, Tokyo (JP)

(21) Appl. No.: 19/238,758

(22) Filed: Jun. 16, 2025

(30) Foreign Application Priority Data
Jan. 30, 2025 (JP) 2025-014266

(51) Int. Cl. H10B 43/27; H10B 43/10

(52) U.S. Cl. CPC H10B 43/27; H10B 43/10

(57) ABSTRACT

A semiconductor storage device according to the present embodiment includes a stacked body. The stacked body includes a first column, a second column, and a separation portion. The first column is provided in a first area of the stacked body and includes a first semiconductor portion. The second column is provided in a second area of the stacked body and includes an insulator. The separation portion extends to separate the first area and separate the second area. The number of layers of the first column is different from the number of layers of the second column and the separation portion. The semiconductor storage device further includes a first bridge provided at a joint portion of the separation portions in adjacent layers. The position of the first bridge is a position at an intermediate portion between an upper end portion and a lower end portion of the first column.

### CROSS REFERENCE TO RELATED APPLICATIONS

This application is based upon and claims the benefit of priority from the prior Japanese Patent Application No. 2025-014266, filed on January 30, 2025, the entire contents of which are incorporated herein by reference.

### FIELD

The embodiments of the present invention relate to a semiconductor storage device and a manufacturing method thereof.

### BACKGROUND

In a three-dimensional non-transitory memory, a structure is known in which a plurality of series of memory cell arrays arranged in the height direction are provided for a single pillar to improve the integration density of memory cells. In such a configuration of a three-dimensional non-transitory memory, word lines stacked in the height direction of the pillar need to be finely divided without collapsing them.

### BRIEF DESCRIPTION OF THE DRAWINGS

FIG. 1 is a perspective view exemplarily illustrating a semiconductor storage device according to a first embodiment;

FIG. 2 is a plan view illustrating a stacked body;

FIG. 3 is a cross sectional view illustrating an exemplary memory cell having a three-dimensional structure;

FIG. 4 is a cross sectional view illustrating the exemplary memory cell having a three-dimensional structure;

FIG. 5 is a plan view illustrating an example of the semiconductor storage device according to the first embodiment;

FIG. 6 is a schematic plan view illustrating arrangement of a connection area and memory cell areas;

FIG. 7A is a perspective view schematically illustrating the connection area of blocks;

FIG. 7B is a perspective view schematically illustrating the connection area of blocks;

FIG. 8A is a plan view illustrating some conductive layers in the connection area in more detail;

FIG. 8B is a plan view illustrating some conductive layers in the connection area in more detail;

FIG. 9 is a cross sectional view illustrating an example of the configuration of the semiconductor storage device according to the first embodiment;

FIG. 10 is a cross sectional view illustrating an example of the configuration of the semiconductor storage device according to the first embodiment;

FIG. 11A is a cross sectional view illustrating an exemplary method for manufacturing the semiconductor storage device according to the first embodiment;

FIG. 11B is a perspective view illustrating the exemplary semiconductor storage device manufacturing method, following FIG. 11A;

FIG. 11C is a perspective view illustrating the exemplary semiconductor storage device manufacturing method, following FIG. 11B;

FIG. 11D is a perspective view illustrating the exemplary semiconductor storage device manufacturing method, following FIG. 11C;

FIG. 11E is a perspective view illustrating the exemplary semiconductor storage device manufacturing method, following FIG. 11D;

FIG. 11F is a perspective view illustrating the exemplary semiconductor storage device manufacturing method, following FIG. 11E;

FIG. 12A is a cross sectional view illustrating an exemplary method for manufacturing the semiconductor storage device according to the first embodiment;

FIG. 12B is a perspective view illustrating the exemplary semiconductor storage device manufacturing method, following FIG. 12A;

FIG. 12C is a perspective view illustrating the exemplary semiconductor storage device manufacturing method, following FIG. 12B;

FIG. 12D is a perspective view illustrating the exemplary semiconductor storage device manufacturing method, following FIG. 12C;

FIG. 12E is a perspective view illustrating the exemplary semiconductor storage device manufacturing method, following FIG. 12D;

FIG. 13 is a plan view illustrating an example of the configuration of a semiconductor storage device according to a second embodiment;

FIG. 14 is a plan view illustrating an example of the configuration of a semiconductor storage device according to a third embodiment;

FIG. 15 is a plan view illustrating an example of the configuration of a semiconductor storage device according to a fourth embodiment;

FIG. 16 is a plan view illustrating an example of the configuration of a semiconductor storage device according to a fifth embodiment; and

FIGS. 17A to 17G are cross sectional views illustrating an example of the configuration of a semiconductor storage device according to a sixth embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor storage device according to the present embodiment includes a stacked body in which a plurality of first conductive layers and a plurality of first insulating layers are alternately stacked in a first direction. The stacked body includes a first column, a second column, and a separation portion. The first column is provided in a first area of the stacked body and includes a first semiconductor portion and a first insulator portion, the first semiconductor portion extending in the first direction inside the stacked body, the first insulator portion being provided on an outer peripheral surface of the first semiconductor portion. The second column is provided in a second area of the stacked body, extends in the first direction inside the stacked body, and includes an insulator. The separation portion extends the first direction and a second direction intersecting the first direction in the stacked body to separate the first area and separate the second area. The number of layers of the first column is different from the number of layers of the second column and the separation portion. The semiconductor storage device further includes a first bridge provided at a joint portion of the separation portions in adjacent layers. The position of the first bridge in the first direction is a position in the first direction at an intermediate portion between an upper end portion and a lower end portion of the first column.

### First embodiment

First example of configuration of semiconductor storage device

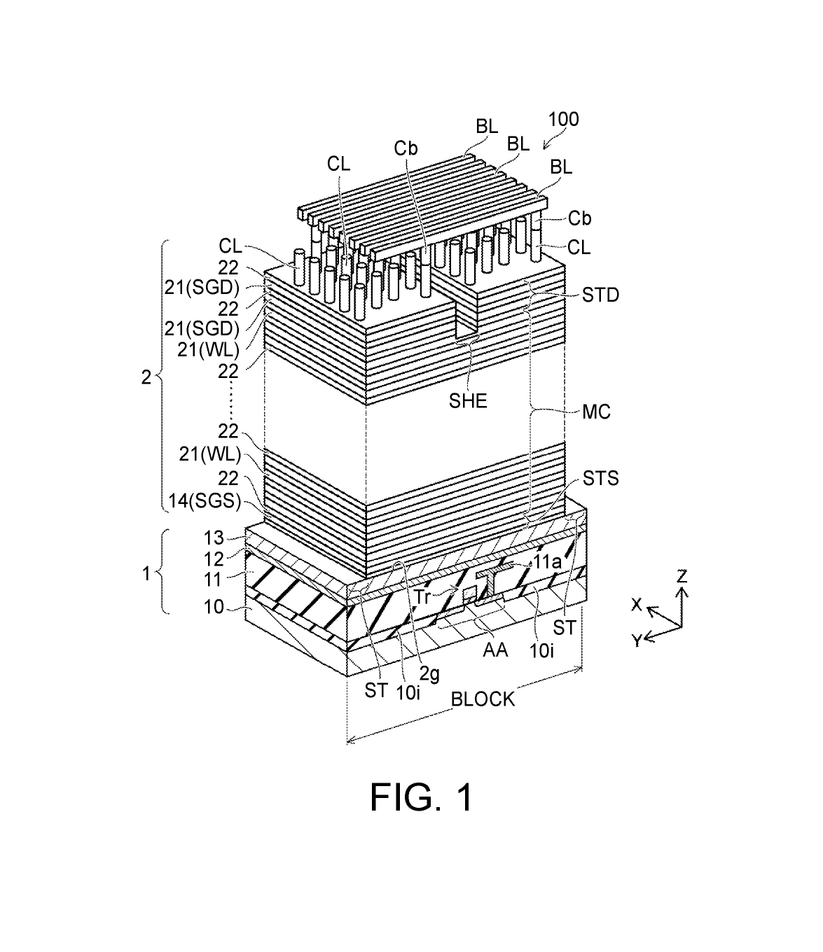

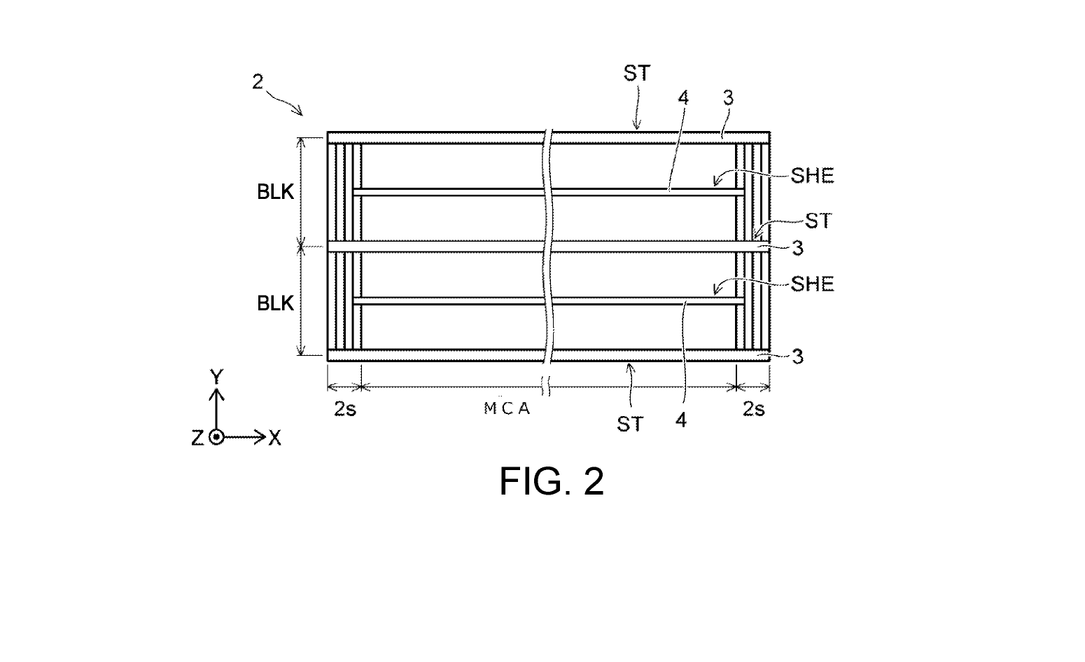

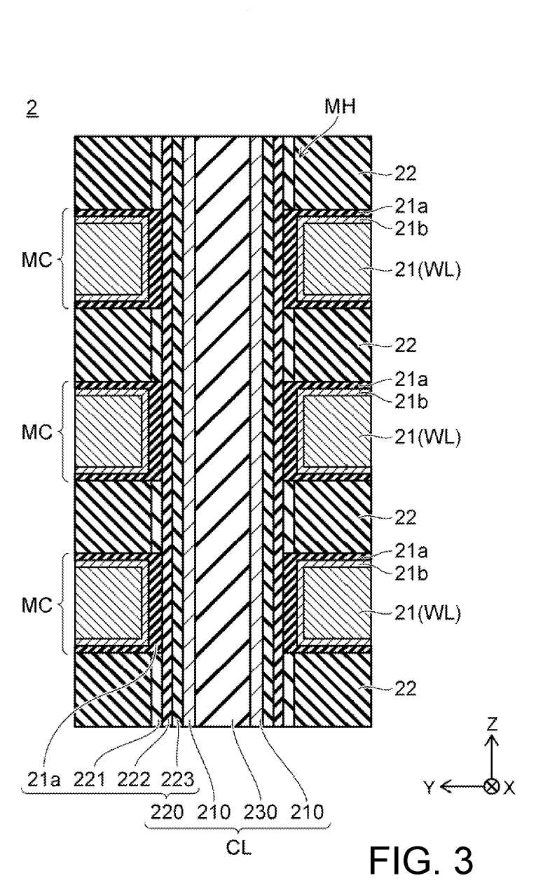

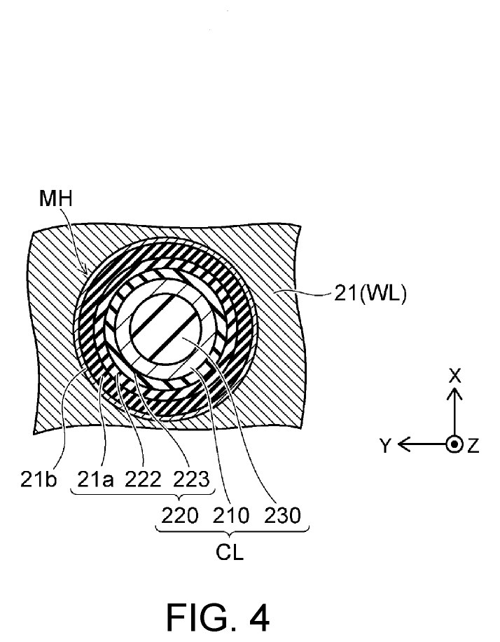

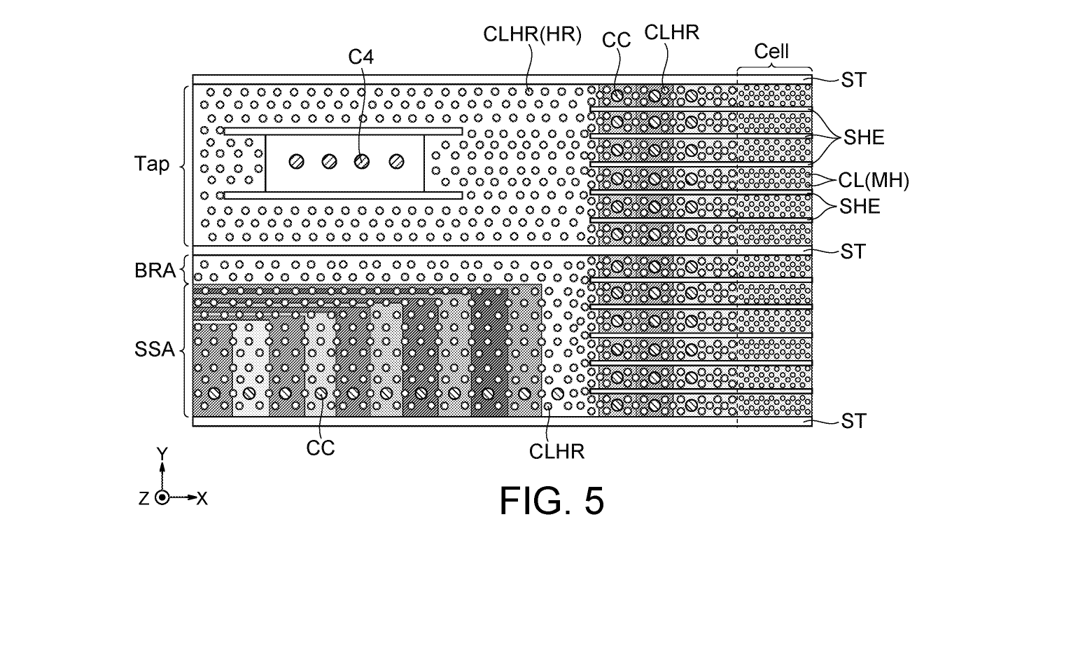

FIG. 1 is a perspective view exemplarily illustrating a semiconductor storage device 100 according to a first embodiment. FIG. 2 is a plan view illustrating a stacked body 2. In the present specification, the stacking direction of the stacked body 2 is defined as a Z-axis direction. One direction orthogonal to the Z-axis direction is defined as a Y-axis direction. A direction orthogonal to the Z-axis and Y-axis directions is defined as an X-axis direction. FIGS. 3 and 4 are cross sectional views illustrating an exemplary memory cell having a three-dimensional structure. FIG. 5 is a plan view illustrating an example of the semiconductor storage device 100 according to the first embodiment. As illustrated in FIGS. 1 to 5, the semiconductor storage device 100 according to the first embodiment is a non-transitory memory including a memory cell array having a three-dimensional structure.

The semiconductor storage device 100 includes a base portion 1, the stacked body 2, a plate-like portion 3, a plurality of columns CL, and a plurality of insulator columns CLHR.

The base portion 1 includes a semiconductor wafer (substrate) 10, an insulating film 11, a conductive film 12, and a semiconductor portion 13. The insulating film 11 is provided on the semiconductor wafer 10. The conductive film 12 is provided on the insulating film 11. The semiconductor portion 13 is provided on the conductive film 12. The semiconductor wafer 10 is, for example, a silicon wafer. The semiconductor wafer 10 has, for example, a p-type conductivity. For example, an element separation area 10i is provided in a surface area of the semiconductor wafer 10. The element separation area 10i is, for example, an insulation area including a silicon oxide film and defines an active area AA in the surface area of the semiconductor wafer 10. The source and drain areas of a transistor Tr are provided in the active area AA. The transistor Tr constitutes a complementary metal oxide semiconductor (CMOS) circuit as a control circuit of a non-transitory memory. The insulating film 11 includes, for example, a silicon oxide film and insulates the transistor Tr. A wiring 11a is provided in the insulating film 11. The wiring 11a is electrically connected to the transistor Tr. The conductive film 12 contains a conductive metal, for example, tungsten (W). The semiconductor portion 13 contains, for example, n-type silicon. Part of the semiconductor portion 13 may include undoped silicon.

The stacked body 2 is positioned above the semiconductor portion 13 in the Z-axis direction. The stacked body 2 is constituted by alternately stacking a plurality of conductive layers 21 as a plurality of first conductive layers and a plurality of insulating layers 22 as a plurality of first insulating layers in the Z-axis direction. The plurality of conductive layers 21 are stacked with an insulating layers 22 interposed therebetween so as to be spaced from each other. The conductive layers 21 contain a conductive metal, for example, tungsten. The insulating layers 22 contain, for example, silicon oxide. The insulating layers 22 insulate the conductive layers 21 from each other. The number of stacked conductive layers 21 and the number of stacked insulating layers 22 are optional. The insulating layers 22 may be, for example, gaps. For example, an insulating film 2g is provided between the stacked body 2 and the semiconductor portion 13. The insulating film 2g includes, for example, a silicon oxide film. The insulating film 2g may contain a high-permittivity dielectric material having a relative permittivity higher than that of silicon oxide. The high-permittivity dielectric material may be, for example, an oxide including a hafnium oxide film.

The conductive layers 21 include at least one source-side selection gate SGS, a plurality of word lines WL, and at least one drain-side selection gate SGD. The source-side selection gate SGS is a gate electrode of a source-side selection transistor STS. Each word line WL is a gate electrode of a memory cell MC. The drain-side selection gate SGD is a gate electrode of a drain-side selection transistor STD. The source-side selection gate SGS is provided in a lower area of the stacked body 2. The drain-side selection gate SGD is provided in an upper area of the stacked body 2. The lower area refers to an area of the stacked body 2 on a side closer to the base portion 1, and the upper area refers to an area of the stacked body 2 on a side farther from the base portion 1. The word lines WL are provided between the source-side selection gate SGS and the drain-side selection gate SGD.

The Z-axis directional thickness of an insulating layer 22 insulating the source-side selection gate SGS from the word lines WL among the plurality of insulating layers 22 may be larger than, for example, the Z-axis directional thickness of an insulating layer 22 insulating the word lines WL from each other. In addition, a cover insulating film may be provided on the uppermost insulating layers 22 farthest from the base portion 1. The cover insulating film contains, for example, silicon oxide.

The semiconductor storage device 100 includes a plurality of memory cells MC connected in series between the source-side selection transistor STS and the drain-side selection transistor STD. A structure in which the source-side selection transistor STS, the memory cells MC, and the drain-side selection transistor STD are connected in series is called "memory string" or "NAND string". The memory string is connected to, for example, bit lines BL through contacts Cb. The bit lines BL are provided above the stacked body 2 and extend in the Y-axis direction.

A plurality of deep slits ST and a plurality of shallow slits SHE are provided in the stacked body 2. As illustrated in FIG. 2, the slits ST extend in the X-axis direction in planar layout. The slits ST penetrate through the stacked body 2 from the upper end of the stacked body 2 to the base portion 1 at a section in the Z direction (stacking direction) and are provided in the stacked body 2. The plate-like portion 3 in FIG. 2 is provided in each slit ST. For example, an insulating film such as a silicon oxide film is used as the plate-like portion 3. Alternatively, the plate-like portion 3 may be made of a conductive metal such as a conductive material (for example, tungsten or copper), which is electrically connected to the semiconductor portion 13 and may be electrically insulated from the stacked body 2 by an insulating film. The slits SHE extend in the X-axis direction substantially in parallel with the slits ST in planar layout. The slits SHE are provided from the upper end of the stacked body 2 to an intermediate portion of the stacked body 2 at a section in the Z direction. For example, an insulator 4 is provided in each slit SHE. For example, an insulating film such as a silicon oxide film is used as the insulator 4.

As illustrated in FIG. 2, the stacked body 2 includes staircase portions 2s and a memory cell array MCA. Each staircase portion 2s is provided at an edge portion of the stacked body 2. The memory cell array MCA is sandwiched or surrounded by the staircase portions 2s. The slit ST is provided from the staircase portion 2s at one end of the stacked body 2 to the staircase portion 2s at the other end of the stacked body 2 through the memory cell array MCA. The slit SHE is provided at least in the memory cell array MCA.

A part of the stacked body 2 sandwiched by two slits ST (plate-like portions 3) is referred to as a block BLK. A block constitutes, for example, a minimum unit of data erasure. The slits SHE (insulators 4) are provided in a block. The stacked body 2 between a slit ST and a slit SHE is referred to as a finger. The drain-side selection gate SGD is partitioned for each finger. Accordingly, during data writing and reading, one of the fingers in a block can be brought into a selected state by the drain-side selection gate SGD.

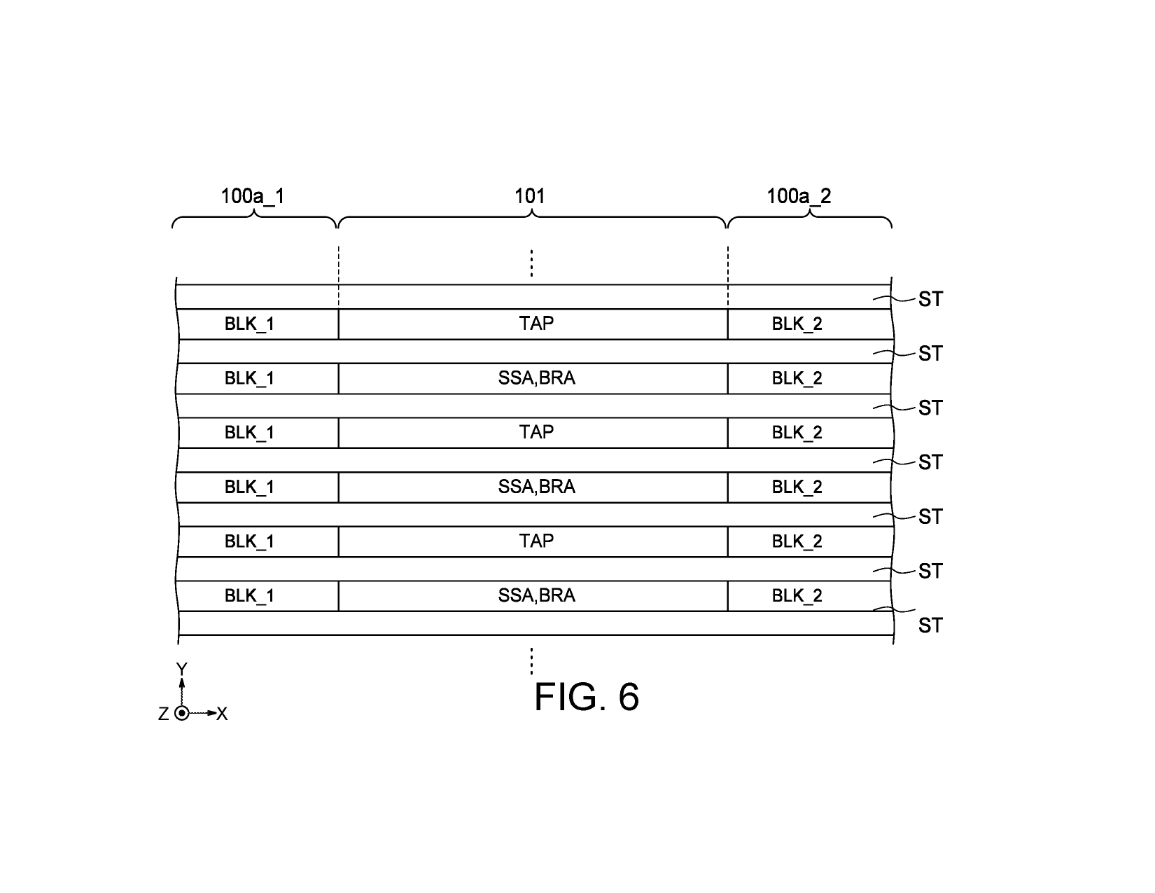

As illustrated in FIG. 5, the memory cell array MCA includes a cell area Cell and other areas. In the cell area Cell, a plurality of columns CL are provided in memory holes MH. The areas other than the cell area Cell include a tap area Tap, a staircase area SSA, and a bridge area BRA. The tap area Tap is provided in a block BLK adjacent to the staircase area SSA and the bridge area BRA in the Y direction with a slit ST interposed therebetween. As illustrated in FIG. 6, the tap area Tap may be provided between cell areas in the X direction. The staircase area SSA and the bridge area BRA may be provided between cell areas in the X direction. The staircase area SSA is an area in which a plurality of contact plugs CC are provided. As illustrated in FIG. 6, the bridge area BRA is provided to electrically connect wiring layers of the word lines WL of a block BLK adjacent thereto in the X direction with the staircase area SSA interposed therebetween. The tap area Tap is an area in which contact plugs C4 are provided. The contact plugs CC and C4 extend in, for example, the Z-axis direction. The contact plugs CC are electrically connected to, for example, the conductive layers 21, respectively. The contact plugs C4 are electrically connected to, for example, the wiring 11a for power supply to the transistor Tr or the like. For example, a low-resistance metal such as copper or tungsten is used as the contact plugs CC and C4.

An insulating film (not illustrated) is provided around each of the contact plugs CC and C4. With this configuration, the contact plugs CC and C4 are electrically insulated from the stacked body 2. Accordingly, while being insulated from the stacked body 2, the contact plugs CC and C4 can electrically connect wirings and the like above the stacked body 2 to wirings and the like below the stacked body 2. For example, an insulating film such as a silicon oxide film is used as the insulating film.

The plurality of columns CL are provided in the respective memory holes MH provided in the stacked body 2. The memory holes MH extend from the upper end of the stacked body 2 into the stacked body 2 and the semiconductor portion 13 through the stacked body 2 in the stacking direction of the stacked body 2 (Z-axis direction). As illustrated in FIGS. 3 and 4, each of the plurality of columns CL includes a semiconductor body 210 as a semiconductor pillar, a memory film 220, and a core layer 230. The semiconductor body 210 extends in the stacking direction (Z direction) in the stacked body 2. The semiconductor body 210 is electrically connected to the semiconductor portion 13. The memory film 220 has a charge trapping portion between the semiconductor body 210 and each conductive layer 21. A plurality of columns CL each selected from a finger are commonly connected to one bit line BL through contacts Cb. Each column CL is provided in, for example, a cell area (Cell) in FIG. 5.

As illustrated in FIGS. 3 and 4, the shape of each memory hole MH on an X-Y plane is, for example, circle or ellipse. A block insulating film 21a that constitutes part of the memory film 220 may be provided between each conductive layer 21 and the corresponding insulating layer 22. The block insulating film 21a is, for example, a silicon oxide film or a metallic oxide film. One example of the metallic oxide is aluminum oxide. A barrier film 21b may be provided between each conductive layer 21 and the corresponding insulating layer 22 and between each conductive layer 21 and the memory film 220. For the barrier film 21b, for example, in a case where the conductive layer 21 is tungsten, a stacked structure film of titanium nitride or titanium, for example, is selected. The block insulating film 21a suppresses back tunneling of electric charge from the conductive layer 21 toward the memory film 220. The barrier film 21b improves adhesion between the conductive layer 21 and the block insulating film 21a.

The shape of the semiconductor body 210 is, for example, tubular. The semiconductor body 210 contains, for example, silicon. The silicon is, for example, polysilicon obtained by crystallizing amorphous silicon. The semiconductor body 210 is, for example, undoped silicon. The semiconductor body 210 may be p-type silicon. The semiconductor body 210 serves as a channel for each of the drain-side selection transistor STD, the memory cells MC, and the source-side selection transistor STS.

Part of the memory film 220 other than the block insulating film 21a is provided between the inner wall of the memory hole MH and the semiconductor body 210. The shape of the memory film 220 is, for example, tubular. A plurality of memory cells MC have storage regions between the semiconductor body 210 and the conductive layers 21 as the word lines WL and are stacked in the Z-axis direction. The memory film 220 includes, for example, a cover insulating film 221, a charge trapping film 222, and a tunnel insulating film 223. The semiconductor body 210, the charge trapping film 222, and the tunnel insulating film 223 extend in the Z-axis direction.

The cover insulating film 221 is provided between each insulating layer 22 and the charge trapping film 222. For example, silicon oxide is used as the cover insulating film 221. The cover insulating film 221 is provided to protect the charge trapping film 222 from etching when sacrifice films provided between the insulating layers 22 are replaced with the conductive layers 21 in a manufacturing process. The cover insulating film 221 may be removed from between each conductive layer 21 and the memory film 220 in a replacing process. In this case, as illustrated in FIGS. 3 and 4, for example, the block insulating film 21a is provided between each conductive layer 21 and the charge trapping film 222. The cover insulating film 221 may not be provided in a case where the replacing process is not used to form the conductive layers 21.

The charge trapping film 222 is provided between each block insulating film 21a and the cover insulating film 221, and the tunnel insulating film 223. The charge trapping film 222 contains, for example, silicon nitride and includes trap sites in the film that trap charges. Part of the charge trapping film 222 sandwiched between each conductive layer 21 as a word line WL and the semiconductor body 210 serves as a charge trapping portion and constitutes the storage region of the corresponding memory cell MC. The threshold voltage of the memory cell MC changes in accordance with the presence or absence of electric charge in the charge trapping portion or the amount of charge trapped in the charge trapping portion. Accordingly, the memory cell MC can hold information.

The tunnel insulating film 223 is provided between the semiconductor body 210 and the charge trapping film 222. For example, silicon oxide or combination of silicon oxide and silicon nitride is used as the tunnel insulating film 223. The tunnel insulating film 223 is a potential barrier between the semiconductor body 210 and the charge trapping film 222. For example, when electrons are injected from the semiconductor body 210 into the charge trapping portion (write operation) and when holes are injected from the semiconductor body 210 into the charge trapping portion (erase operation), the electrons and holes pass (tunnel) through the potential barrier of the tunnel insulating film 223.

The core layer 230 fills the inner space of the tubular semiconductor body 210. The shape of the core layer 230 is, for example, columnar. For example, an insulating film such as a silicon oxide film is used as the core layer 230.

Each of the plurality of insulator columns CLHR illustrated in FIG. 5 is provided in a hole HR provided in the stacked body 2. The hole HR is provided in the Z-axis direction from the upper end of the stacked body 2 into the stacked body 2 and the semiconductor portion 13 through the stacked body 2. For example, an insulator such as a silicon oxide film is used as the insulator columns CLHR. Each insulator column CLHR may have the same structure as each column CL. Each insulator column CLHR is provided in, for example, the tap area Tap, the staircase area SSA, and the bridge area BRA. The insulator columns CLHR function as support members for holding void spaces formed in the staircase area and the tap area when sacrifice films (not illustrated) are replaced with the conductive layers 21 (replacing process). The hole HR of each insulator column CLHR has a radius (width in the X direction or the Y direction) larger than that of the corresponding column CL.

As illustrated in FIG. 1, the semiconductor storage device 100 further includes a semiconductor portion 14. The semiconductor portion 14 is positioned between the stacked body 2 and the semiconductor portion 13. The semiconductor portion 14 is provided between an insulating layer 22 closest to the semiconductor portion 13 among the insulating layers 22 and the insulating film 2g. The semiconductor portion 14 has, for example, an n-type conductivity. The semiconductor portion 14 functions as, for example, the source-side selection gate SGS.

FIG. 6 is a schematic plan view illustrating arrangement of a connection area 101 and memory cell areas 100a. The memory cell areas 100a include a first memory cell area 100a_1 and a second memory cell area 100a_2 that are adjacent to each other. The first memory cell area 100a_1 and the second memory cell area 100a_2 each include a plurality of blocks BLK. In the Y direction, the plurality of blocks BLK are divided from each other by the slits ST extending in the X direction.

The first memory cell area 100a_1 and the second memory cell area 100a_2 each include the above-described plurality of columns CL (memory holes MH) and include a plurality of three-dimensionally disposed memory cells. The memory cells are formed at intersect points of the plurality of word lines WL and the plurality of columns CL.

For sake of simplicity, each block BLK belonging to the first memory cell area 100a_1 is referred to as a block BLK_1. Each block BLK belonging to the second memory cell area 100a_2 is referred to as a block BLK_2.

The connection area 101 is provided between the first memory cell area 100a_1 and the second memory cell area 100a_2 in the X direction intersecting the Z direction and includes the tap area Tap, the staircase area SSA, and the bridge area BRA for each block BLK. Hereinafter, the staircase area SSA and the bridge area BRA are also referred to as the staircase area SSA or the like.

As described above, the tap area Tap and the staircase area SSA or the like are adjacent to each other in the Y direction with a slit ST interposed therebetween. As illustrated in FIG. 6, the tap area Tap and the staircase area SSA or the like are alternately provided in the Y direction. Although not illustrated, the tap area Tap and the staircase area SSA or the like are alternately provided in the X direction as well. In other words, the tap area Tap and the staircase area SSA or the like are alternately provided in the Y direction with the slits ST interposed therebetween and are alternately provided in the X direction with a memory area Cell (block BLK) interposed therebetween.

In the staircase area SSA, the selection gate line (source-side selection gate) SGS and end portions of the plurality of respective word lines WL are stepped in the X direction in order from a lower layer and formed in a staircase shape. In other words, the selection gate line SGS and the plurality of word lines WL in the staircase area SSA each include, at its end portion, a terrace portion (also referred to as staircase, staircase portion, or lead-out portion) that does not overlap a lower wiring layer (conductive layer). The contact plugs CC in FIG. 5 are formed on the respective terrace portions. The selection gate line SGS and the plurality of word lines WL can each have voltage applied thereto separately through the contact plugs CC. In this manner, the staircase area SSA is provided as a terrace area for connecting a plurality of contacts to a plurality of respective conductive layers connected to the selection gate line SGS and the plurality of word lines WL.

Note that, the contact plugs CC are electrically connected to the contact plugs C4 in the tap area in FIG. 5 through upper wirings (not illustrated) and electrically connected to a row decoder provided below the memory cell array through the contact plugs C4. Accordingly, the row decoder can control voltages of the conductive layers 21 (word lines WL) through the contact plugs CC. The diameters of the contact plugs CC and C4 are larger than the diameters of the insulator columns CLHR.

In the bridge area BRA, a plurality of third conductive layers corresponding to the selection gate line SGS and the plurality of word lines WL, respectively, are stacked in the Z direction with intervals therebetween. The third conductive layers electrically connect the conductive layers 21 (selection gate line SGS and plurality of word lines WL) in the first memory cell area 100a_1, respectively, to the conductive layers 21 (selection gate line SGS and plurality of word lines WL) in the second memory cell area 100a_2. Accordingly, the first and second memory cell areas 100a_1 and 100a_2 can function as one memory cell array MCA.

In this manner, since the connection area 101 is disposed at an intermediate portion of the memory cell array MCA, the contact plugs CC are positioned in the middle of wiring of the word lines WL, which can shorten the distances from the contact plugs CCa to end portions of the word lines WL. Accordingly, the semiconductor storage device 100 can swiftly supply power to the end portions of the word lines WL through the contact plugs CC, facilitating voltage control of the word lines WL. Moreover, since the memory cell areas 100a_1 and 100a_2 can be disposed on the respective sides of one connection area 101, it is possible to increase the scale (storage capacity) of the memory cell array MCA while maintaining operation speed.

The bridge area BRA has the same stacked body structure as the first and second memory cell areas 100a_1 and 100a_2. Accordingly, the stacked body of the bridge area BRA is constituted by alternately stacking a plurality of conductive layers 21 and a plurality of insulating layers 22 in the Z-axis direction. In other words, the plurality of conductive layers 21 as a plurality of third conductive layers are stacked with an insulating layers 22 interposed therebetween so as to be spaced from each other. As described above, the insulating layers 22 may be air gaps.

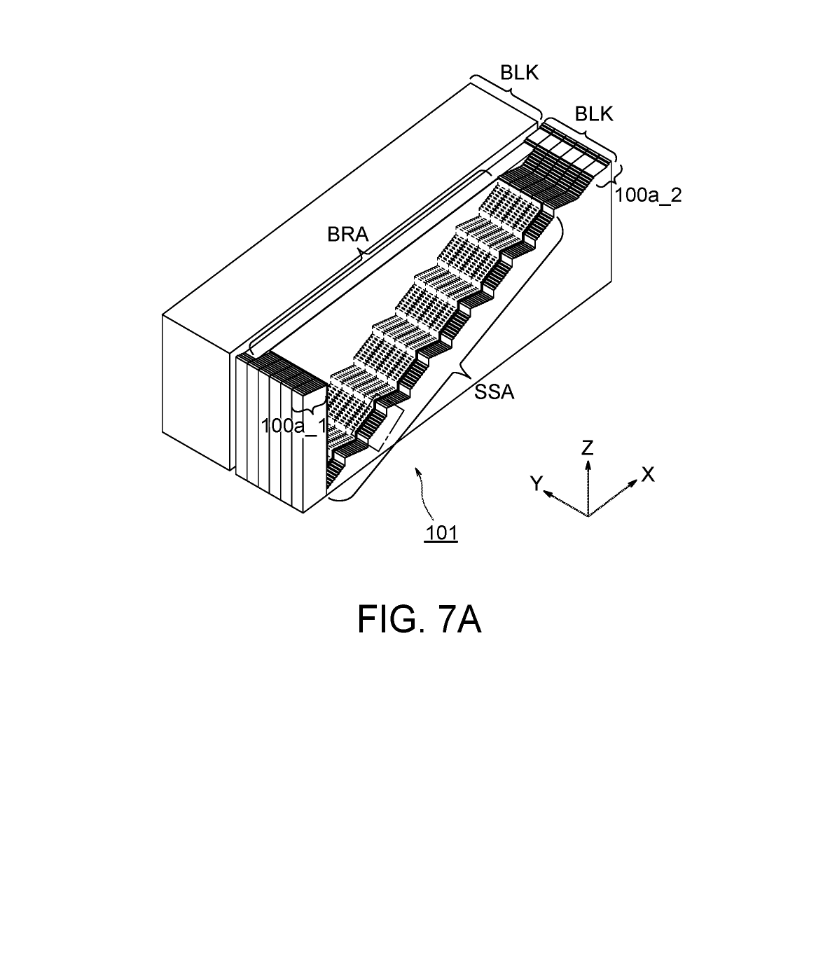

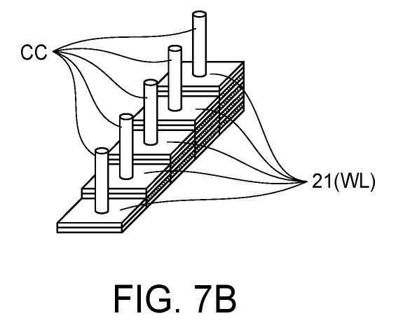

FIGS. 7A and 7B are perspective views schematically illustrating the connection area 101 of a block BLK. The staircase area SSA of the connection area 101 is provided in a staircase shape so as to connect the plurality of contact plugs CC to the plurality of conductive layers 21 (word lines WL), respectively. In the bridge area BRA, the plurality of conductive layers 21 electrically connect the conductive layers 21 (word lines WL) between the first and second memory cell areas 100a_1 and 100a_2.

In the connection area 101, the bridge area BRA is provided adjacent to the staircase area SSA in the Y direction (direction substantially orthogonal to the extending direction of the slits ST) and not formed in a staircase shape. Accordingly, the bridge area BRA includes the same number of conductive layers 21 and the same number of insulating layers 22 as in the stacked body 2 in the first and second memory cell areas 100a_1 and 100a_2.

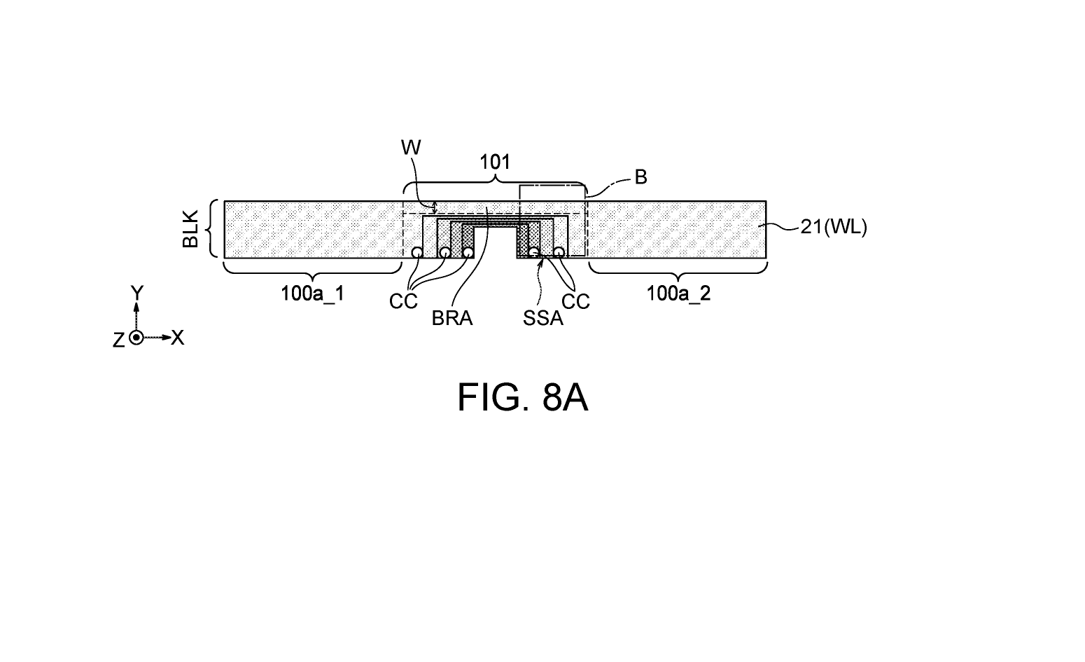

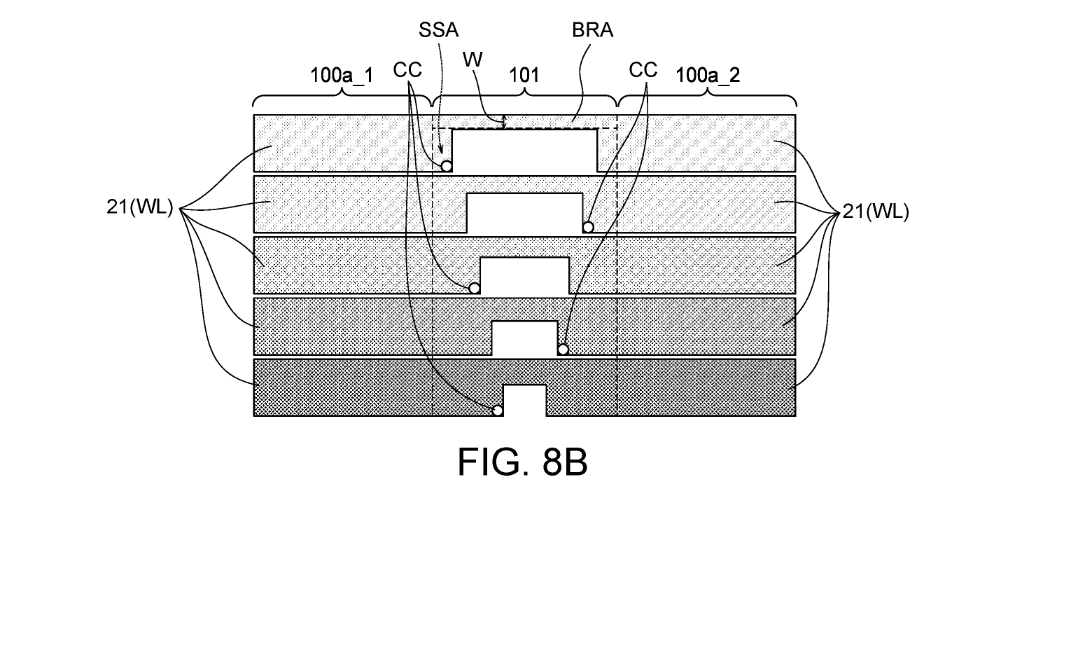

FIGS. 8A and 8B are plan views illustrating some conductive layers 21 in the connection area 101 in more detail. FIG. 8A illustrates a state in which the conductive layers 21 are stacked, and FIG. 8B separately illustrates each conductive layer 21. In FIGS. 8A and 8B, five conductive layers 21 are illustrated. The number of the conductive layers 21 of course may be equal to or smaller than four or may be equal to or larger than six. Note that, in FIGS. 8A and 8B, one block BLK is illustrated whereas illustration of the columns CL (memory holes MH), the insulator columns CLHR, and the slits SHE in FIG. 5 is omitted.

As illustrated in FIG. 8A, the staircase area SSA of the connection area 101 is formed in a staircase shape such that the surface (tread surface) of each conductive layer 21 is visible in the Z direction. The surface (tread surface) of each conductive layer 21 has a size (area) in which a contact plug CC is connectable in the Z direction. In FIG. 8A, staircase portions in the staircase area SSA are provided on the respective sides of the connection area 101 in the X direction so as to face each other. As illustrated in FIGS. 8A and 8B, one contact plug CC is provided on each conductive layer 21 in the staircase area SSA and connected onto the tread surface of the conductive layer 21. For example, in the example illustrated in FIGS. 8A and 8B, the contact plugs CC are alternately connected to left and right staircase portions in the staircase area SSA. More specifically, a contact plug CC is connected to the tread surface of the uppermost conductive layer 21 at the staircase portion on the left side in the staircase area SSA. A contact plug CC is connected to the tread surface of the second uppermost conductive layer 21 at the staircase portion on the right side in the staircase area SSA. A contact plug CC is connected to the tread surface of the third uppermost conductive layer 21 at the staircase portion on the left side in the staircase area SSA. A contact plug CC is connected to the tread surface of the fourth uppermost conductive layer 21 at the staircase portion on the right side in the staircase area SSA. A contact plug CC is connected to the tread surface of the fifth uppermost (lowermost) conductive layer 21 at the staircase portion on the left side in the staircase area SSA.

Note that, the staircase area SSA may be provided only on one side in the X direction in the connection area 101. In this case, the contact plugs CC are connected to tread surfaces at a staircase portion provided on the one side in the connection area 101.

Since one contact plug CC is provided on each conductive layer 21, the conductive layers 21 in a memory cell area on a side where the contact plugs CC is not connected are electrically connected to the contact plugs CC through the bridge area BRA. For example, no contact plugs CC are provided on the uppermost conductive layer 21 in the second memory cell area 100a_2 on the right side. Thus, the uppermost conductive layer 21 in the second memory cell area 100a_2 on the right side is electrically connected to a contact plug CC provided on the uppermost conductive layer 21 in the second memory cell area 100a_2 on the left side through the uppermost conductive layer 21 in the bridge area BRA. No contact plugs CC are provided on the second uppermost conductive layer 21 in the second memory cell area 100a_2 on the left side. Thus, the second uppermost conductive layer 21 in the second memory cell area 100a_2 on the left side is electrically connected to a contact plug CC provided on the second uppermost conductive layer 21 in the second memory cell area 100a_2 on the right side through the second uppermost conductive layer 21 in the bridge area BRA. In this manner, one of the memory cell areas 100a_1 and 100a_2 on the respective sides of the connection area 101 is electrically connected to the contact plugs CC provided in the other memory cell area through the bridge area BRA.

Note that the structure illustrated in FIGS. 4 and 5 are exemplary, and for example, the tap area Tap and the contact plugs C4 may not be provided.

Configuration of bridge

Structures around the slits ST and SHE will be described below in detail.

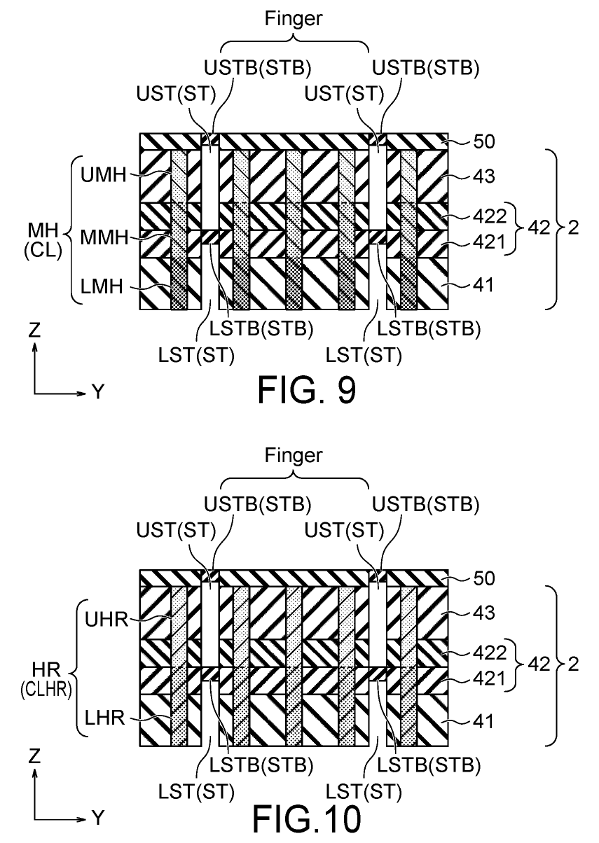

FIG. 9 is a cross sectional view illustrating an example of the configuration of the semiconductor storage device 100 according to the first embodiment. FIG. 10 is a cross sectional view illustrating an example of the configuration of the semiconductor storage device 100 according to the first embodiment. FIG. 9 illustrates a cross sectional view of a cell area. FIG. 10 illustrates a cross sectional view of a staircase area.

The stacked body 2 includes stacked bodies 41, 42, and 43. The stacked bodies 41, 42, and 43 are a stacked body 41 in a lower layer, a stacked body 42 in an intermediate layer, and a stacked body 43 in an upper layer, respectively.

The stacked body 42 includes a lower layer 421 and an upper layer 422.

Each memory hole MH illustrated in FIG. 9 and a column CL (not illustrated) provided in the memory hole MH have a three-layer structure.

Each memory hole MH includes memory holes LMH, MMH, and UMH. The memory holes LMH, MMH, and UMH are memory holes MH corresponding to the stacked body 41 in the lower layer, the stacked body 42 in the intermediate layer, and the stacked body 43 in the upper layer, respectively.

Each column CL includes columns LCL, MCL, and UCL filling in the memory holes LMH, MMH, and UMH. The columns LCL, MCL, and UCL are columns CL corresponding to the stacked body 41 in the lower layer, the stacked body 42 in the intermediate layer, and the stacked body 43 in the upper layer, respectively.

Note that the memory holes LMH, MMH, and UMH illustrated in FIG. 9 have constant widths in the Z-axis direction, and the widths may differ. For example, the widths of the memory holes LMH, MMH, and UMH may be smaller from the upper ends of the memory holes LMH, MMH, and UMH to the lower ends.

Note that joint layers may be provided at connection portions between the memory holes LMH, MMH, and UMH.

Slits ST illustrated in FIGS. 9 and 10 have a two-layer structure.

Each slit ST includes slits LST and UST. The slits LST and UST are slits ST in lower and upper layers, respectively.

Each slit ST is filled with a non-illustrated material (plate-like portion 3). Each slit ST is filled with, for example, a metal film such as tungsten or an insulating film.

The semiconductor storage device 100 illustrated in FIG. 9 further includes an insulating layer 50 and a bridge STB.

The insulating layer 50 is provided on the stacked body 2. The insulating layer 50 is separated by the slits ST. The insulating layer 50 is, for example, a tetra-ethoxy silane(TEOS)-SiO₂ film.

The bridge STB is provided in each slit ST (separation portion). The bridge STB can suppress inclination of two adjacent fingers. Moreover, the bridge STB can suppress deformation of the fingers. The bridge STB includes, for example, an insulating film.

Each bridge STB illustrated in FIG. 9 includes a lower bridge LSTB and an upper bridge USTB.

The bridge LSTB is provided at a position in the Z-axis direction on the upper surface of the lower layer 421 (upper portion of the slit LST). The bridge USTB is provided at a position in the Z-axis direction on the upper surface of the insulating layer 50.

The bridges LSTB and USTB include, for example, an insulator such as a silicon oxide film.

The bridge LSTB is provided at a joint portion of the slits ST (slits LST and UST) in adjacent layers. The position of the bridge LSTB in the Z-axis direction is a position in the Z-axis direction at an intermediate portion between upper and lower end portions of the memory hole MMH.

The bridges USTB are provided between portions of the insulating layer 50 separated by the slits ST, in other words, at upper portions of the slits UST.

Similarly to the slits ST, holes HR illustrated in FIG. 10 and columns CLHR (not illustrated) filling the holes HR have a two-layer structure.

Each hole HR includes holes LHR and UHR. The holes LHR and UHR are holes HR in lower and upper layers, respectively.

Each column CLHR includes columns LCLHR and UCLHR. The columns LCLHR and UCLHR are columns CLHR in lower and upper layers, respectively.

As illustrated in FIGS. 9 and 10, the number of layers of each memory hole MH (column CL) is different from the number of layers of each hole HR (the column CLHR) and each slit ST.

Note that the holes LHR and UHR illustrated in FIG. 10 have constant widths in the Z-axis direction, but the widths may differ. For example, the widths of the holes LHR and UHR may be smaller from the upper ends of the holes LHR and UHR to the lower ends.

Methods for forming the bridges STB, the memory holes MH, and the holes HR will be described below.

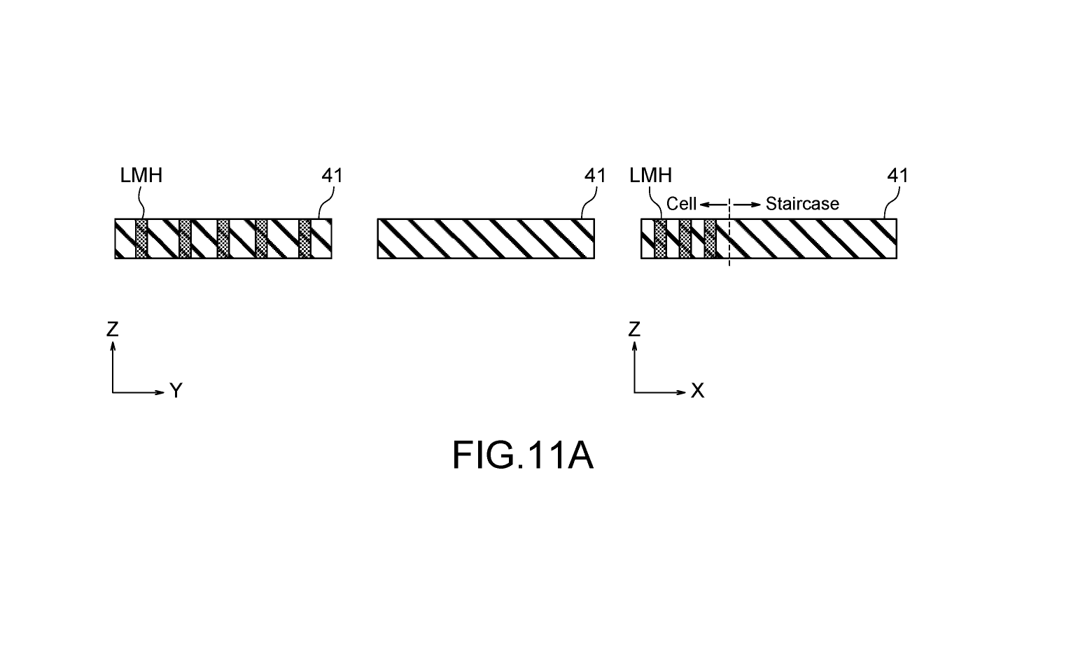

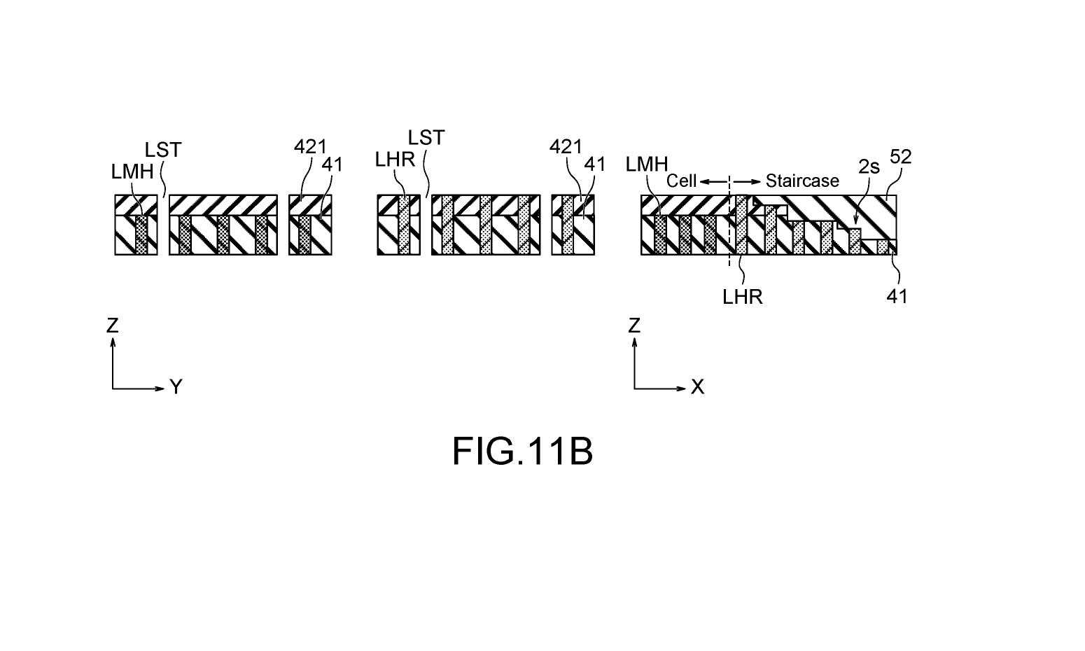

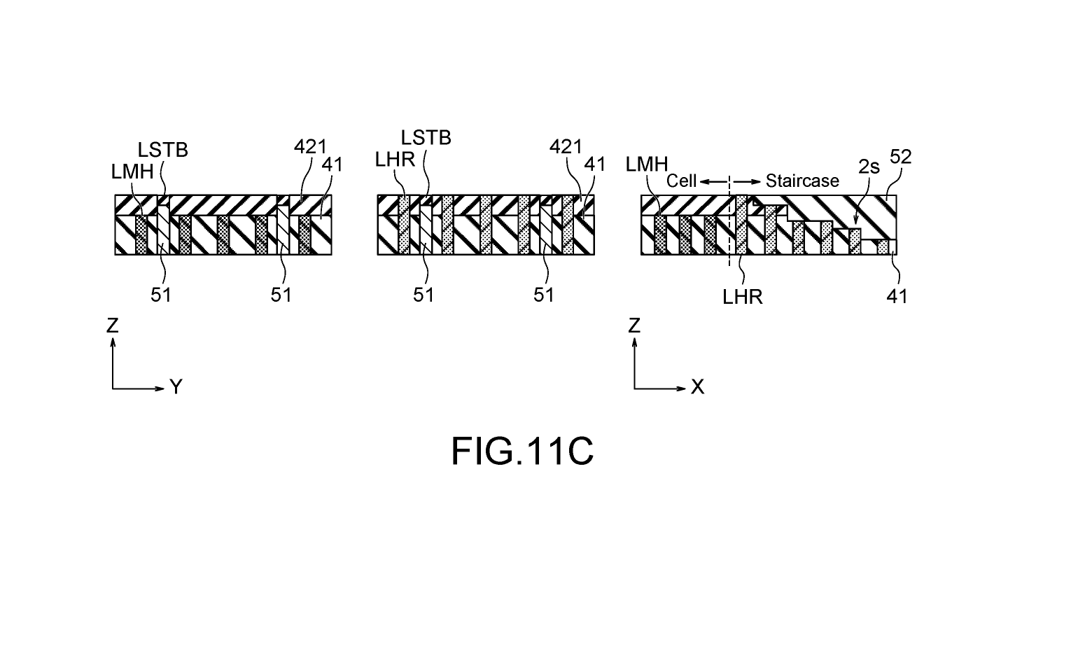

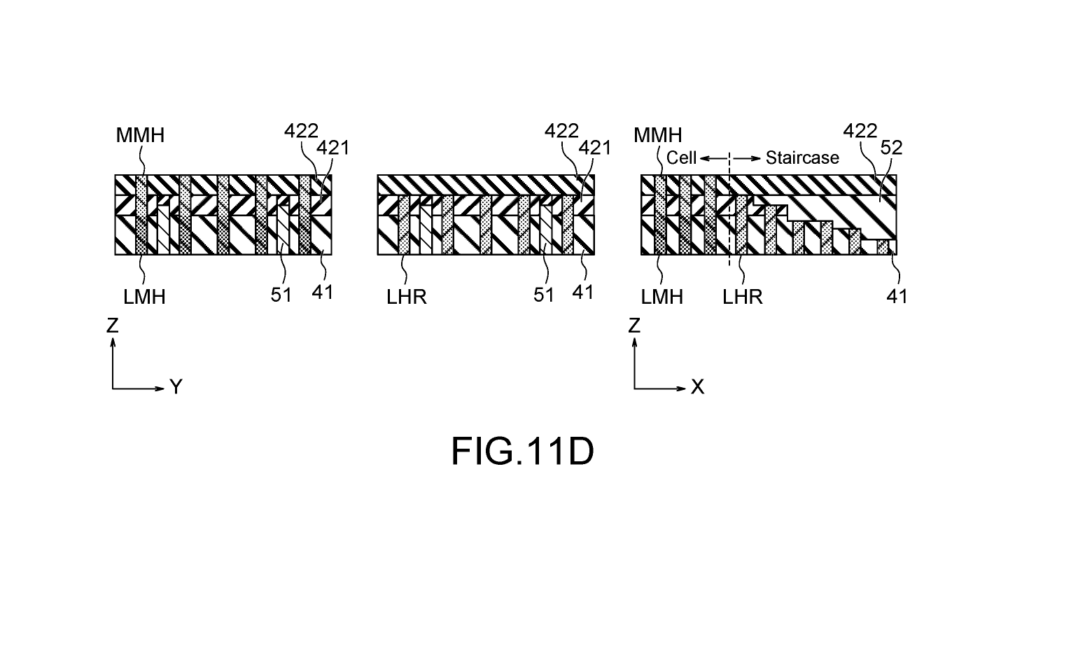

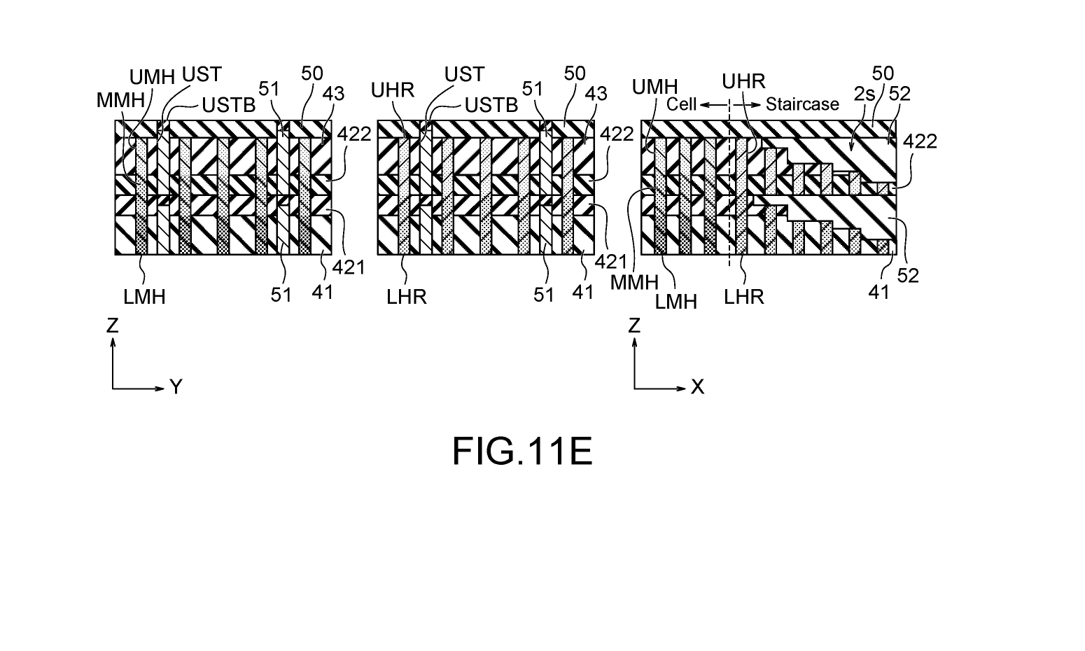

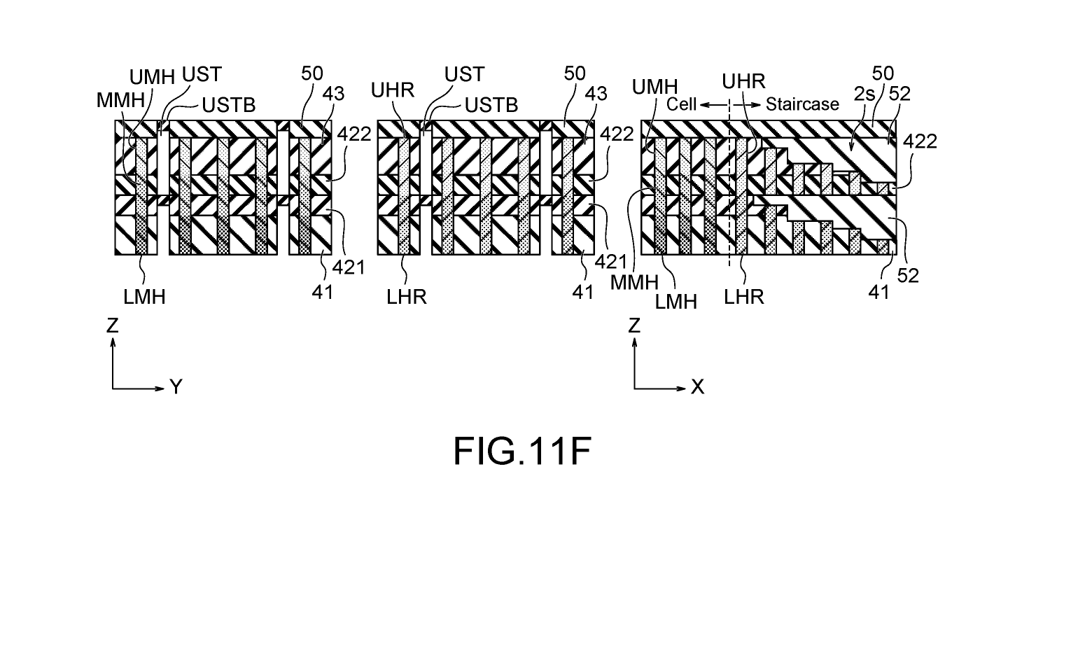

FIGS. 11A to 11F are cross sectional views illustrating an exemplary method for manufacturing the semiconductor storage device 100 according to the first embodiment. The left side in each of FIGS. 11A to 11F illustrates a cross sectional view of a cell area having a three-layer structure when viewed in the X-axis direction. The middle in each of FIGS. 11A to 11F illustrates a cross sectional view of a staircase area having a two-layer structure when viewed in the X-axis direction. The right side in each of FIGS. 11A to 11F illustrates a cross sectional view of the cell area and the staircase area when viewed in the Y-axis direction.

First, as illustrated in FIG. 11A, the stacked body 41 is formed and the memory holes LMH are formed. The stacked body 41 includes a stacked body in which a plurality of sacrifice films 21c and a plurality of insulating layers 22 are alternately stacked in the Z-axis direction. The memory holes LMH extend in the Z-axis direction inside the stacked body 41. The memory holes LMH may be filled with sacrifice films.

Subsequently, as illustrated in FIG. 11B, the lower layer 421 of the stacked body 42 is formed on the stacked body 41, and the holes LHR, the slits LST, and the staircase portion 2s of the staircase area are formed. The staircase portion 2s is flattened by, for example, an insulating film 52 (TEOS-SiO₂ film). The lower layer 421 includes a stacked body in which a plurality of sacrifice films 21c and a plurality of insulating layer 22 are alternately stacked in the Z-axis direction. The holes LHR extend in the Z-axis direction inside the stacked body 41 and the lower layer 421. The slits LST extend in the X-axis direction inside the stacked body 41 and the lower layer 421 to separate the cell area and separate the staircase area. The holes LHR may be filled with sacrifice films.

Subsequently, as illustrated in FIG. 11C, the bridges LSTB are formed inside the slits LST at positions along the upper surfaces of the lower layer 421 and the holes LHR. The bridges LSTB are provided at the upper portions of the slits LST. Note that the other portions of the slits LST than the bridges LSTB are filled with sacrifice films 51.

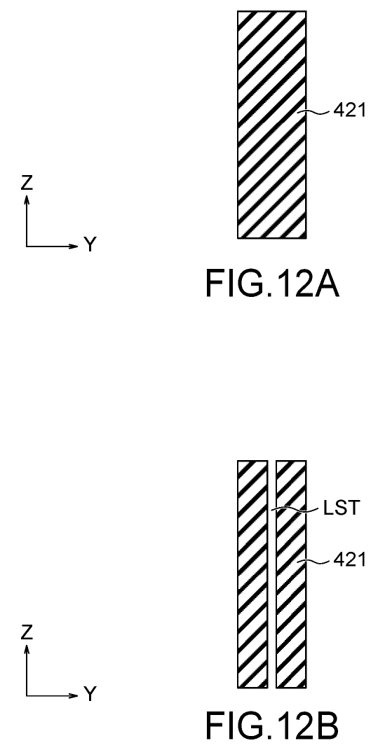

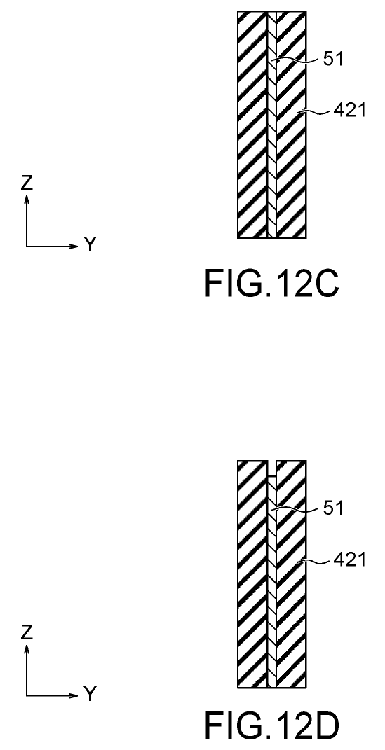

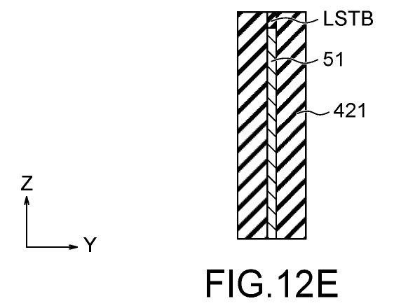

The method for forming the bridges LSTB will be described below in detail with reference to FIGS. 12A to 12E.

FIGS. 12A to 12E are cross sectional views illustrating an exemplary method for manufacturing the semiconductor storage device 100 according to the first embodiment.

First, as illustrated in FIG. 12A, the lower layer 421 is formed. The lower layer 421 includes a stacked body in which a plurality of sacrifice films 21c and a plurality of insulating layer 22 are alternately stacked in the Z-axis direction.

Subsequently, as illustrated in FIG. 12B, each slit LST is formed in the lower layer 421.

Subsequently, as illustrated in FIG. 12C, the slit LST is filled with a sacrifice film 51.

Subsequently, as illustrated in FIG. 12D, part of the sacrifice film 51 in the slit LST is removed. Accordingly, a recessed portion is formed in an area from which the sacrifice film 51 is removed. The removal of part of the sacrifice film 51 is performed by, for example, reactive ion etching (RIE).

Subsequently, as illustrated in FIG. 12E, the recessed portion formed by removing the sacrifice film 51 is filled with an insulating film (for example, silicon oxide film). Accordingly, a bridge LSTB is formed inside the slit LST at a position along the upper surface of the lower layer 421.

Note that the bridges USTB at positions along the upper surface of the insulating layer 50 are similarly formed.

Subsequently, as illustrated in FIG. 11D, the upper layer 422 is formed on the lower layer 421, and the memory holes MMH are formed on the memory holes LMH. The upper layer 422 includes a stacked body in which a plurality of sacrifice films 21c and a plurality of insulating layer 22 are alternately stacked in the Z-axis direction. The memory holes MMH extend in the Z-axis direction inside the lower layer 421 and the upper layer 422. The memory holes MMH may be filled with sacrifice films.

Subsequently, as illustrated in FIG. 11E, the stacked body 43 is formed on the upper layer 422, and the memory holes UMH on the memory holes MMH, the holes UHR on the holes LHR, the staircase portion 2s of the staircase area, the slits UST, and the bridges USTB are formed. The stacked body 43 includes a stacked body in which a plurality of sacrifice films 21c and a plurality of insulating layer 22 are alternately stacked in the Z-axis direction. The bridges USTB are provided at the upper portions of the slits UST. Note that the other portions of the slits UST than the bridges USTB are filled with the sacrifice films 51.

Subsequently, as illustrated in FIG. 11F, the sacrifice films 51 in the slits LST and UST are removed. Accordingly, the structure illustrated in FIGS. 9 and 10 is obtained.

As described above, according to the first embodiment, the number of layers of each column CL is different from the number of layers of each column CLHR and each slit ST. Each bridge LSTB is provided at a joint portion of the slits ST in adjacent layers. The position of each bridge LSTB in the Z-axis direction is a position in the Z-axis direction at an intermediate portion between the upper and lower end portions of the corresponding column CL.

Each bridge USTB is provided between portions of the insulating layer 50 separated by the slits ST.

The bridges LSTB and USTB can suppress finger inclination due to left-right asymmetry of a finger portion in the bit line BL direction (Y-axis direction). This can suppress the risk of occurrence of defects such as leakage caused by the metal film filled in the slits ST coming into contact with the contacts Cb due to finger inclination.

Moreover, the bridges LSTB can suppress bowing deformation of central portions of the slits ST in the depth direction (side surfaces of the slits ST) along with an increased number of layers of the word lines WL. This can suppress the risk of occurrence of a defect in which the slits ST are obstructed.

Each column CL has a three-layer structure, and each column CLHR and each slit ST have a two-layer structure. With this combination, it is possible to provide the bridges LSTB at central positions of the stacked body 2 in the Z-axis direction, and it is easier to further suppress bowing deformation.

Note that the numbers of layers are not limited to the above-described example. The number of layers of each column CL in the memory area only needs to be different from the number of layers of each column CLHR and each slit ST.

### Second embodiment

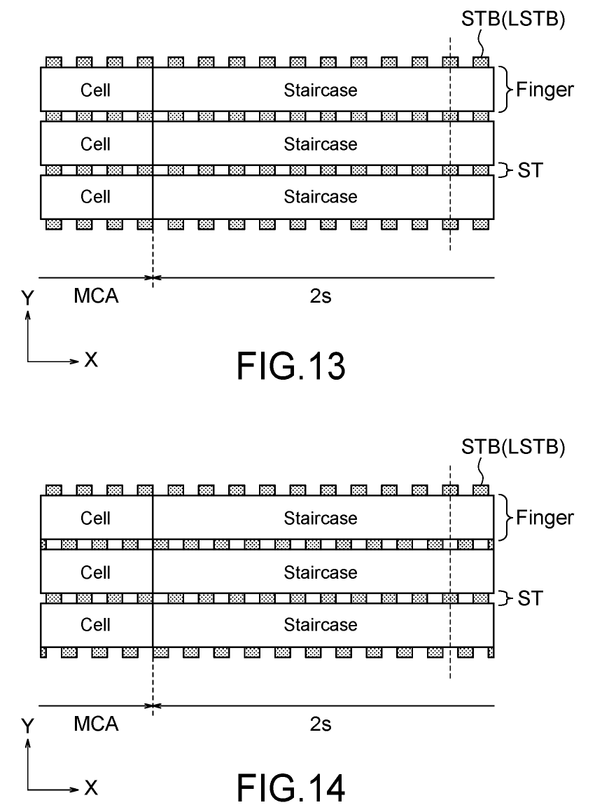

FIG. 13 is a plan view illustrating an example of the configuration of the semiconductor storage device 100 according to a second embodiment. The second embodiment describes exemplary arrangement of the bridges STB.

The bridges STB are discontinuously (intermittently) provided in the X direction.

In the example illustrated in FIG. 13, the bridges STB are disposed without being offset between adjacent slits ST. This can further suppress bowing deformation of central portions of the slits ST in the depth direction.

In other words, the bridges STB (bridges LSTB) at the slits ST adjacent to each other in the Y-axis direction intersecting the Z-axis direction and the X-axis direction are disposed at positions substantially identical to each other in the X-axis direction.

The bridges STB may be disposed as in the second embodiment. The semiconductor storage device 100 according to the second embodiment can achieve the same effects as in the first embodiment.

### Third embodiment

FIG. 14 is a plan view illustrating an example of the configuration of the semiconductor storage device 100 according to a third embodiment. The third embodiment describes exemplary arrangement of the bridges STB.

The bridges STB are discontinuously provided in the X direction.

In the example illustrated in FIG. 14, the bridges STB are disposed in a staggered manner. Specifically, the bridges STB are disposed with a half-pitch offset in the X direction. This can suppress process adverse effects during the replacing process of replacing the sacrifice films 21c with the conductive layers 21.

In other words, the bridges STB (bridges LSTB) at the slits ST adjacent to each other in the Y-axis direction intersecting the Z-axis direction and the X-axis direction are disposed at positions different from each other in the X-axis direction.

The bridges STB may be disposed as in the third embodiment. The semiconductor storage device 100 according to the third embodiment can achieve the same effects as in the first embodiment.

### Fourth embodiment

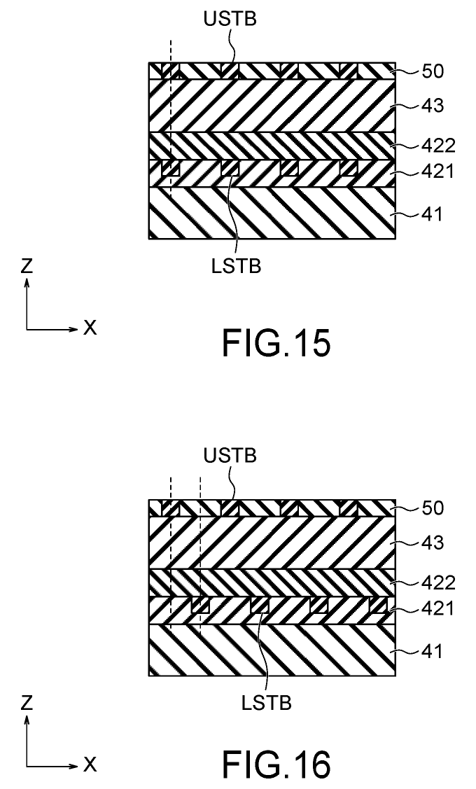

FIG. 15 is a cross sectional view illustrating an example of the configuration of the semiconductor storage device 100 according to a fourth embodiment. The fourth embodiment describes exemplary arrangement of the bridges STB.

In the example illustrated in FIG. 15, the bridges LSTB and USTB are disposed so as to overlap each other when viewed in the Z-axis direction. This can further suppress bowing deformation at central portions of the slits ST in the depth direction.

In other words, the bridges LSTB and USTB are disposed at positions substantially identical to each other in the X-axis direction. Note that, in a case in which the bridges USTB are provided in two layers or more, the bridges USTB adjacent to each other in the Z-axis direction may be disposed at positions substantially identical to each other in the X-axis direction.

The bridges STB may be disposed as in the fourth embodiment. The semiconductor storage device 100 according to the fourth embodiment can achieve the same effects as in the first embodiment.

### Fifth embodiment

FIG. 16 is a cross sectional view illustrating an example of the configuration of the semiconductor storage device 100 according to a fifth embodiment. The fifth embodiment describes exemplary arrangement of the bridges STB.

In the example illustrated in FIG. 16, the bridges LSTB and USTB are disposed so as not to overlap each other when viewed in the Z-axis direction.

In other words, the bridges LSTB and USTB are disposed at positions different from each other in the X-axis direction. Note that, in a case in which the bridge USTB are provided in two layers or more, the bridges USTB adjacent to each other in the Z-axis direction may be disposed at positions different from each other in the X-axis direction.

The bridges STB may be disposed as in the fifth embodiment. The semiconductor storage device 100 according to the fifth embodiment can achieve the same effects as in the first embodiment.

### Sixth embodiment

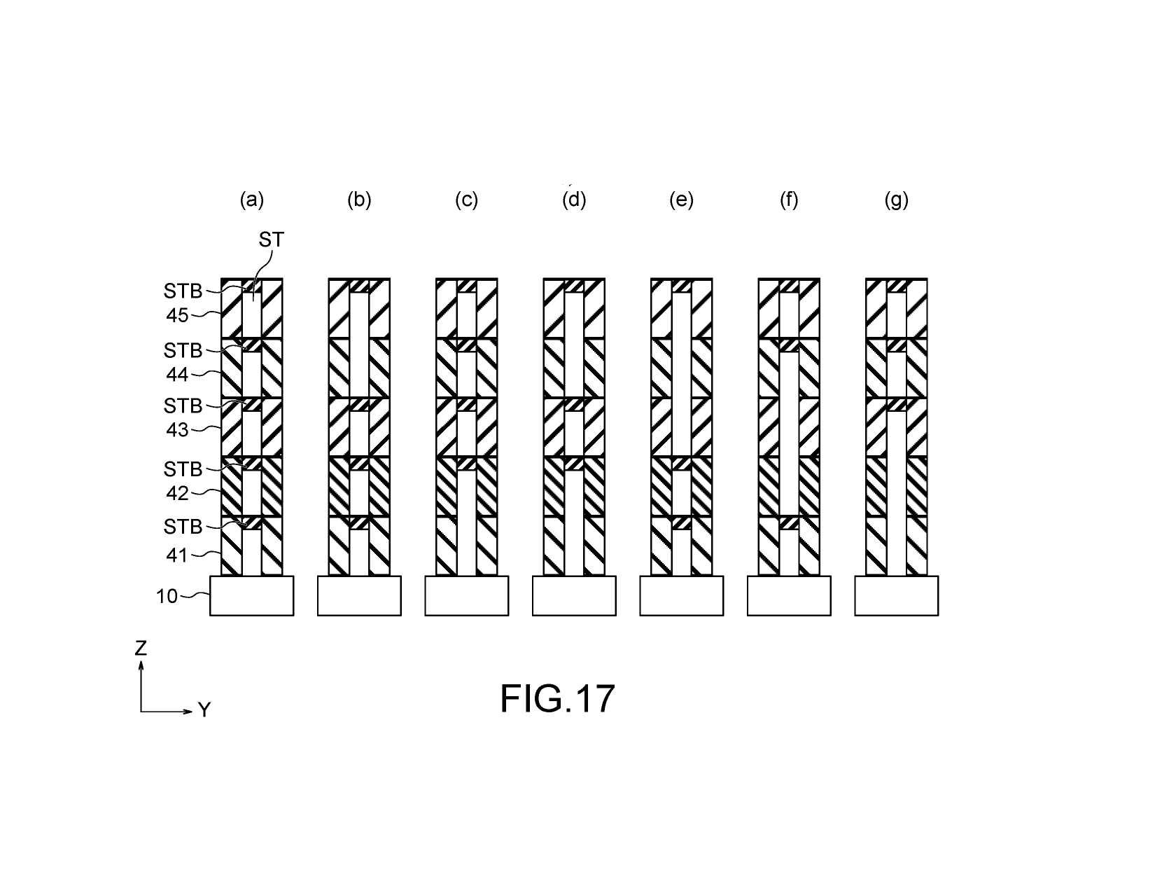

FIGS. 17A to 17G are cross sectional views illustrating an example of the configuration of the semiconductor storage device 100 according to a sixth embodiment. The sixth embodiment describes exemplary arrangement of the bridges STB.

Each bridge LSTB is provided at a position in the Z-axis direction at a joint portion of slits ST in some or all layers among adjacent layers.

A hole HR illustrated in FIGS. 17A to 17G and a column CLHR and slits ST corresponding to the hole HR have a five-layer structure. In other words, the staircase area has a five-layer structure. FIGS. 17A to 17G illustrate seven examples of disposition of the bridges STB.

To suppress defects due to bowing deformation at central portions of the slits ST in the depth direction, the number of places where the bridges STB are not provided is preferably as small as possible. Moreover, when the number of places where the bridges STB are not provided is the same, the bridges STB are preferably disposed in lower layers. In addition, the places where the bridge STB are not provided are preferably not continuous. From this perspective, defects due to bowing deformation at central portions of the slits ST in the depth direction can be suppressed in the order of (a) > (b) > (c) > (d) > (e) > (f) > (g).

The bridges STB may be disposed as in the sixth embodiment. The semiconductor storage device 100 according to the sixth embodiment can achieve the same effects as in the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising a stacked body in which a plurality of first conductive layers and a plurality of first insulating layers are alternately stacked in a first direction, wherein
the stacked body includes
a first column provided in a first area of the stacked body and including a first semiconductor portion and a first insulator portion, the first semiconductor portion extending in the first direction inside the stacked body, the first insulator portion being provided on an outer peripheral surface of the first semiconductor portion,
a second column provided in a second area of the stacked body, extending in the first direction inside the stacked body, and including an insulator, and
a separation portion extending in the first direction and a second direction intersecting the first direction in the stacked body to separate the first area and separate the second area,
the number of layers of the first column is different from the number of layers of the second column and the separation portion,
the semiconductor storage device further includes a first bridge provided at a joint portion of the separation portions in adjacent layers, and
the position of the first bridge in the first direction is the position in the first direction at an intermediate portion between an upper end portion and a lower end portion of the first column.

2. The semiconductor storage device of claim 1, further comprising:
a second insulating layer provided on the stacked body and separated by the separation portion; and
a second bridge provided between separated portions of the second insulating layer.

3. The semiconductor storage device of claim 1, wherein the first bridge is provided at a position in the first direction at a joint portion of the separation portions in some or all layers among adjacent layers.

4. The semiconductor storage device of claim 1, wherein the first bridge includes an insulator.

5. The semiconductor storage device of claim 1, wherein the first bridges at the separation portions adjacent to each other in a third direction intersecting the first direction and the second direction are disposed at positions substantially identical to each other in the second direction.

6. The semiconductor storage device of claim 1, wherein the first bridges at the separation portions adjacent to each other in a third direction intersecting the first direction and the second direction are disposed at positions different from each other in the second direction.

7. The semiconductor storage device of claim 1, further comprising:
a second insulating layer provided on the stacked body and separated by the separation portion; and
a second bridge provided between separated portions of the second insulating layer,
wherein the first bridge and the second bridge are disposed at positions substantially identical to each other in the second direction.

8. The semiconductor storage device of claim 1, further comprising:
a second insulating layer provided on the stacked body and separated by the separation portion; and
a second bridge provided between separated portions of the second insulating layer,
wherein the first bridge and the second bridge are disposed at positions different from each other in the second direction.

9. The semiconductor storage device of claim 1, comprising a plurality of the first bridges intermittently provided in the second direction.

10. The semiconductor storage device of claim 1, wherein the stacked body in the second area has a staircase structure.

11. A semiconductor storage device manufacturing method comprising:
forming a first stacked body in which a plurality of first sacrifice layers and a plurality of first insulating layers are alternately stacked in a first direction;
forming a first hole in a first area of the first stacked body, the first hole extending in the first direction inside the first stacked body;
forming a second stacked body in which the plurality of first sacrifice layers and the plurality of first insulating layers are alternately stacked in the first direction on the first stacked body;
forming a second hole in a second area of the first stacked body and the second stacked body, the second hole extending in the first direction inside the first stacked body and the second stacked body, and forming a first separation portion extending in the first direction and a second direction intersecting the first direction to separate the first area and separate the second area in the first stacked body and the second stacked body;
forming a third bridge provided at an upper portion of the first separation portion;
forming a third stacked body in which the plurality of first sacrifice layers and the plurality of first insulating layers are alternately stacked in the first direction on the second stacked body; and
forming a third hole on the first hole, the third hole extending in the first direction inside the second stacked body and the third stacked body.
